(19) United States
(12) Patent Application Publication
(10) Pub. No.: US 2026/0189187 A1
(43) Pub. Date: Jul. 2, 2026

(54) DC COUPLED AMPLIFIER AND EQUALIZER CIRCUIT

(71) Applicant: MACOM Technology Solutions Holdings, Inc., Lowell, MA (US)

(72) Inventors: Wayne Kennan, Lowell, MA (US); Stefano D'Agostino, Lowell, MA (US); Trong Phan, Lowell, MA (US)

(21) Appl. No.: 19/434,800

(22) Filed: Dec. 29, 2025

Related U.S. Application Data
(60) Provisional application No. 63/740,839, filed on Dec. 31, 2024.

(51) Int. Cl. H03F 1/02

(52) U.S. Cl. CPC H03F 1/0211; H03F 2200/451

(57) ABSTRACT

Systems, circuits, and methods for amplifying signals are provided. An illustrative circuit may include a pre-driver stage having a first current mirror that sets a fixed Direct Current (DC) current within the pre-driver stage and an output stage coupled with the pre-driver stage. The output stage may receive a bias voltage from the pre-driver stage to set an input gate voltage of the output stage, where the output stage further includes a second current mirror to set a bias current of the output stage.

### CROSS-REFERENCE TO RELATED APPLICATION

This application claims priority to and the benefit of U.S. Provisional Application No. 63/740,839, filed Dec. 31, 2024, entitled “DC COUPLED AMPLIFIER AND EQUALIZER CIRCUIT”. The entire disclosure of the application listed above is hereby incorporated herein by reference, in its entirety, for all that it teaches and for all purposes.

### FIELD OF THE DISCLOSURE

The present disclosure is generally directed toward circuits and, in particular, toward amplifier circuits, driver circuits, and equalizer circuits.

### BACKGROUND

High speed data communication over a channel can lead to attenuation of high frequency components of the transmitted signals. Attenuation of the high frequency components may result in degraded signal quality and limit transmit speeds, leading to reduced bandwidth. To overcome this drawback, numerous data communication systems rely on equalizers to compensate for the unwanted effects of the channel. The equalizers have numerous coefficients (values or settings) which may be adjusted to optimally compensate for the effects of the channel on the signal.

Establishing the equalizer values is a complex task, and incorrectly selecting the coefficient values for the equalizer leads to sub-optimal equalization, which, as described above, reduces bandwidth and data transmit rates. In existing systems, the equalization was made easier by use of additional equalizers, such as use of a decision feedback equalizer (DFE) and/or a feed forward equalizer (FFE). The channel could be characterized from the DFE and FFE post-tap values and this information would be used to establish continuous-time linear equalizer (CTLE) coefficients. However, to gain the benefits of reduced size, cost, and power consumption, many communication systems avoid use of a DFE or FFE.

### SUMMARY

Many equalizer circuits utilize frequency selective circuits to degenerate the amplifying transistors. This effectively means that the frequency selective circuits are placed between the transistor emitter or source and ground. Parasitics in these elements degrade the frequency response and make it difficult to achieve equalization curves that match desired specifications. Typically, the gain peaks very slowly with frequency and then accelerates.

There are situations where it becomes desirable to have gain peaking begin at a very low frequency and then decelerate as frequency increases. Embodiments of the present disclosure propose one or more circuit configurations that enable a passive network to provide such capabilities. In accordance with at least some embodiments, the utilization of a passive network enables some or all of the circuit to be implemented in a production GaAs process, thereby simplifying the production thereof.

In accordance with at least some embodiments, a DC-coupled amplifier is provided. The DC-coupled amplifier may be designed with a bias for the output stage being injected through a termination resistor. The output stage may also have an input gate voltage set by a pre-driver stage.

In some embodiments, a current mirror is provided in the output stage. The current mirror may be used to set the bias current of the output stage.

The DC-coupled circuit architecture(s) depicted and described herein may also support insertion of attenuator and/or equalizer circuits between the pre-driver and output stage. The attenuator and/or equalizer circuits may pass through the DC-coupled voltage.

In some embodiments, a circuit, such as an amplifier circuit, is provided that includes: a pre-driver stage having a first current mirror that sets a fixed Direct Current (DC) current within the pre-driver stage; and an output stage coupled with the pre-driver stage and receiving a bias voltage from the pre-driver stage to set an input gate voltage of the output stage, where the output stage further comprises a second current mirror to set a bias current of the output stage.

In some embodiments, a system is provided that includes: a receiver circuit connected between a communication channel and a deserializer, where the receiver circuit includes: an amplifier having a pre-driver stage and an output stage, where the pre-driver stage includes a first current mirror that sets a fixed Direct Current (DC) current within the pre-driver stage, where the output stage is coupled with the pre-driver stage, where the output stage receives a bias voltage from the pre-driver stage to set an input gate voltage of the output stage, and where the output stage further includes a second current mirror to set a bias current of the output stage.

In some embodiments, a method is provided that includes: providing a Direct Current (DC)-coupled amplifier with an output stage; injecting bias for the output stage of the DC-coupled amplifier through a termination resistor; utilizing a pre-driver stage to set an input gate voltage of the output stage; and providing a current mirror in the output stage to set a bias current of the output stage.

The preceding is a simplified summary to provide a basic understanding of some aspects and embodiments described herein. This summary is not an extensive overview of the disclosed subject matter. It is neither intended to identify key nor critical elements of the disclosure nor delineate the scope thereof. The summary is provided to present some concepts in a simplified form as a prelude to the more detailed description that is presented later.

### BRIEF DESCRIPTION OF THE DRAWINGS

The present disclosure is described in conjunction with the appended figures, which are not necessarily drawn to scale:

FIG. 1 is a block diagram illustrating a communication system according to at least some embodiments of the present disclosure;

FIG. 2A illustrates an amplifier circuit that may be provided as part of a transmitter circuit or receiver circuit according to at least some embodiments of the present disclosure;

FIG. 2B illustrates a differential version of the amplifier circuit of FIG. 2A that may be provided as part of a transmitter circuit or receiver circuit according to at least some embodiments of the present disclosure;

FIG. 3 illustrates details of a first sub-circuit useable as part of an amplifier circuit according to at least some embodiments of the present disclosure;

FIG. 4 illustrates details of a second sub-circuit useable as part of an amplifier circuit according to at least some embodiments of the present disclosure;

FIG. 5 illustrates a block diagram of components useable as part of an amplifier circuit according to at least some embodiments of the present disclosure;

FIG. 6 illustrates a number of possible CTLE profiles that can be created with one or more amplifier circuits according to at least some embodiments of the present disclosure;

FIG. 7A illustrates another amplifier circuit topology that may be provided as part of a transmitter circuit or receiver circuit according to at least some embodiments of the present disclosure;

FIG. 7B illustrates a gain response curve for the circuit of FIG. 7A;

FIG. 7C illustrates a group delay curve for the circuit of FIG. 7A;

FIG. 7D illustrates an input return loss curve for the circuit of FIG. 7A;

FIG. 7E illustrates an output return loss curve for the circuit of FIG. 7A;

FIG. 8A illustrates another amplifier circuit topology that may be provided as part of a transmitter circuit or receiver circuit according to at least some embodiments of the present disclosure;

FIG. 8B illustrates a set of insertion loss curves for the circuit of FIG. 8A using various control voltage values;

FIG. 8C illustrates a set of group delay curves for the circuit of FIG. 8A using various voltage values;

FIG. 9A illustrates a passive equalizer circuit that may be provided as part of an amplifier circuit according to at least some embodiments of the present disclosure;

FIG. 9B illustrates a set of insertion loss curves for the circuit of FIG. 9A using various control voltage and current values;

FIG. 9C illustrates a set of group delay curves for the circuit of FIG. 9A using various control voltage and current values; and

FIG. 10 illustrates a method of configuring and operating an amplifier circuit according to at least some embodiments of the present disclosure.

### DETAILED DESCRIPTION

It is with respect to the above-noted challenges that embodiments of the present disclosure were contemplated. In particular, a system, circuits, and method of operating such circuits are provided that solve the drawbacks associated with existing amplifier circuits, driver circuits, and/or equalizer circuits.

While embodiments of the present disclosure will primarily be described in connection with amplifier circuits used in high-bandwidth applications, it should be appreciated that embodiments of the present disclosure are not so limited. Furthermore, while embodiments of the present disclosure are contemplated for use in connection with linear drive applications, driver amplifiers and transimpedance amplifiers (TIAs) using bipolar junction transistors (BJTs) or field-effect transistors (FETs), and the like, it should be appreciated that embodiments of the present disclosure are not so limited.

Various aspects of the present disclosure will be described herein with reference to drawings that are schematic illustrations of idealized configurations. It should be appreciated that while particular circuit configurations and circuit elements are described herein, embodiments of the present disclosure are not limited to the illustrative circuit configurations and/or circuit elements depicted and described herein. Specifically, it should be appreciated that circuit elements of a particular type or function may be replaced with one or multiple other circuit elements to achieve a similar function without departing from the scope of the present disclosure.

It should also be appreciated that the embodiments described herein may be implemented in any number of form factors. Specifically, the entirety of the circuits disclosed herein may be implemented in silicon as a fully-integrated solution (e.g., as a single Integrated Circuit (IC) chip or multiple IC chips) or they may be implemented as discrete components connected to a Printed Circuit Board (PCB). Additionally, some or all of the components depicted and described herein may be provided as part of a semiconductor die manufactured using a Gallium arsenide (GaAs) process. In other words, the components of the circuits depicted and described herein may be manufactured using a GaAs process without departing from the scope of the present disclosure. In some cases, some or all of the components depicted and described herein may be provided as part of a semiconductor die manufactured using a silicon germanium (SiGe) Bipolar CMOS (BiCMOS) process. In other words, the components of the circuits depicted and described herein may be manufactured using a SiGe MiCMOS process without departing from the scope of the present disclosure.

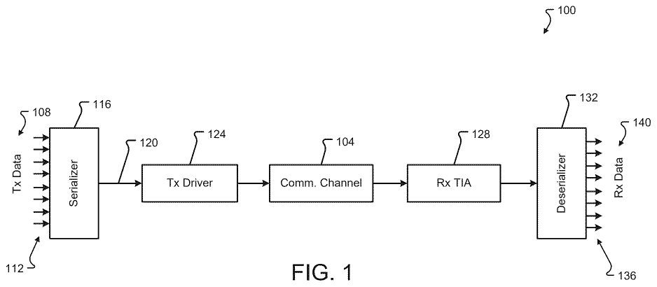

Referring initially to FIG. 1, an illustrative communication system 100 will be described in accordance with at least some embodiments of the present disclosure. The system 100 represents but one possible environment of use of the innovation(s) disclosed herein. As shown, data to be transmitted, referred to as transmit data 108 is provided over two or more parallel paths 112 to a serializer 116. The serializer 116 converts the data received from the two or more parallel paths 112 to a serial stream of data on serial data path 120. The serial stream of data is presented to a transmission driver or circuit 124 which amplifies the signal to a level suitable for transmission over a communication channel 104.

The communication channel 104 may include or correspond to any suitable type of communication channel, such as a channel used for high-speed data transmission. The communication channel 104 may correspond to or include one or more optical fibers. The communication channel 104 may alternatively or additionally correspond to or include one or more electrically-conductive lines. Thus, the data transmitted by the transmission circuit 124 may include an optical signal and/or electrical signal. In one embodiment, the communication channel 104 is a very short reach channel, which may only be several centimeters of PCB trace long. However, the method and apparatus disclosed herein may be used for channels of any length or type, such as but not limited to, fiber channels, circuit board traces, or wired channels, all of which may be any suitable length.

After passing through the communication channel 104, the data is presented to a receiver circuit 128. The receiver circuit 128 may include one or more TIAs. The transmission circuit 124 may include one or more drivers. The transmission circuit 124 and/or receiver circuit 128 may be provided with one or more amplifier circuits comprising one or more equalizer circuits, which may include a CTLE circuit. The equalizer(s) may be configured to reduce the signal attenuating effects of the communication channel 104.

After equalization, the data is provided to a deserializer 132 which converts the serial data stream to a parallel data path on the two or more data paths 136. The data output by the deserializer may be regarded as received data 140 that can be processed by a communication device that includes the receiver circuit 128 and deserializer 132.

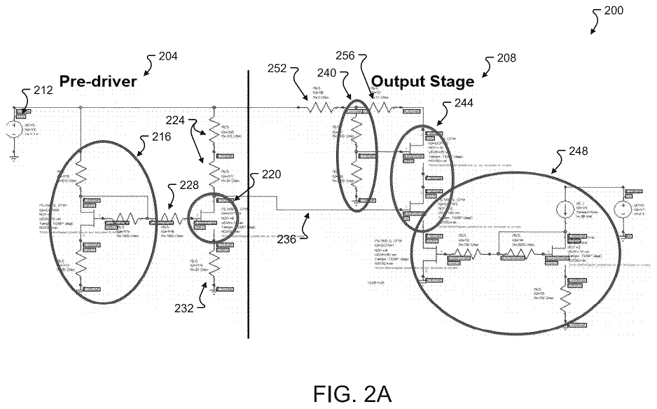

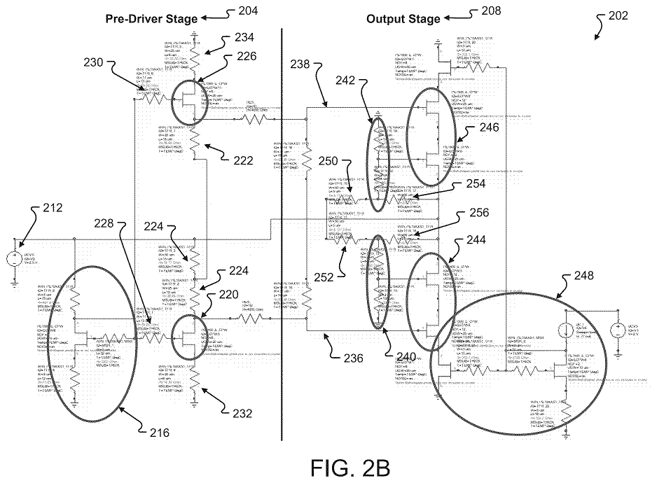

Referring now to FIG. 2A, additional details of an amplifier circuit 200 will be described in accordance with at least some embodiments of the present disclosure. The amplifier circuit 200 may be provided as part of the transmission circuit 124 and/or receiver circuit 128. The amplifier circuit 200 is shown to include a number of different circuit components that support equalization functions and/or amplifying functions.

The amplifier circuit 200 may include a pre-driver stage 204 and an output stage 208 connected to the pre-driver stage 204. As will be described in further detail herein, the output stage 208 may be coupled with the pre-driver stage 204. The output stage 208 may receive a bias voltage from the pre-driver stage 204 to set an input gate voltage of the output stage 208. The pre-driver stage 204 may include a first current mirror 216 to set a fixed DC current in the pre-driver stage 204. The pre-driver stage 204 may further include one or more active transistors 220 positioned between the first current mirror 216 and the output stage 208. The first current mirror 216 may include a transistor having at least one resistor connected to each terminal thereof. The first current mirror 216 may be connected to one or more active RF transistors 220 via a termination resistor 228. The termination resistor 228 may be connected between a base of an RF transistor in the active transistor(s) 220 and a base of a transistor in the first current mirror 216. There may also be one or more resistors 224 connected between the power supply 212 and the collector of the transistor in the active transistor(s) 220. FIG. 1 further illustrates another resistor 232 connected between an emitter of the active transistor(s) 220 and ground.

As noted above, the pre-driver stage 204 may be configured to set an input gate voltage of the output stage 208. In other words, the pre-driver stage 204 may operate as a bias circuit to set a fixed voltage for the output stage 208.

The output stage 208 may include a second current mirror 248 to set a bias current of the output stage 208. The output stage 208 may receive the fixed voltage from the pre-driver stage 204 at an input node 236. Although not depicted, an equalizer circuit may be provided as part of the input node 236. In other words, an equalizer circuit may be provided between the pre-driver stage 204 and the output stage 208 at or near the input node 236 such that the pre-driver stage 204 sets a fixed voltage for the output stage 208. The fixed voltage provided by the pre-driver stage 204 may be provided as an input gate voltage for one or more active transistors 244 in the output stage 208. The active transistor(s) 244 may be provided as part of a cascode between the pre-driver stage 204 and the second current mirror 248.

The output stage 208 may further include a voltage divider 240 between the pre-driver stage 204 and the active transistor(s) 244. The voltage divider 240 may include one or more resistors connected in parallel with the active transistor(s) 244. The voltage divider 240 may also be connected to the pre-driver stage 204 via a first output stage resistor 252 and then connected to one of the active transistor(s) 244 with a second output stage resistor 256. In some embodiments, the voltage divider 240 may be configured to set a voltage on the gates of the active transistor(s) 244.

The second current mirror 248 of the output stage 208 may be configured to set an adjustable DC current in the output stage 208. In some embodiments, the second current mirror 248 may include one or more transistors connected with one or more resistors to provide current mirroring capabilities for the output of the output stage 208.

Referring now to FIG. 2B, additional details of a differential amplifier circuit 202 will be described in accordance with at least some embodiments of the present disclosure. The differential amplifier circuit 202 may be a differential version of the amplifier circuit 200, and is illustrated in include one or more components of the amplifier circuit 200 as well as a number of additional components in both the pre-driver stage 204 and the output stage 208 that enable the differential amplifier circuit 202 to support equalization functions and/or amplifying functions for differential input.

The pre-driver stage 204 of the differential amplifier circuit 202 is illustrated to include, in addition to the pre-driver stage components of the amplifier circuit 200, a second active transistor 226 that is positioned between the first current mirror 216 and the output stage 208. The second active transistor 226 may include a transistor with at least one resistor connected to each terminal thereof. The first current mirror 216 may be connected to the second active transistor 226 (which may be or comprise an active RF transistor) via a termination resistor 230 positioned between the base of the active transistor 226 and a collector of a transistor of the first current mirror 216. There may also be one or more resistors 222 connected between the power supply 212 and the collector of the transistor of the active transistor(s) 226. Another resistor 234 may be connected between the emitter of the active transistor(s) 226 and ground.

The output stage 208 of the differential amplifier circuit 202 is illustrated to include, in addition to the output stage components of the amplifier circuit 200, a second input node 238 whose voltage is set by the pre-driver stage 204. Similar to the amplifier circuit 200, the differential amplifier circuit 202 may include an equalizer circuit as part of the input node 238. The fixed voltage provided by the pre-driver stage 204 at the second input node 238 may be provided as input gate voltage for one or more active transistors 246 in the output stage 208. The active transistor(s) 246 may be provided as part of a cascode between the pre-driver stage 204 and the second current mirror 248. The use of the second input node 238 and the active transistor(s) 246 in addition to the input node 236 and the active transistor(s) 244 enables the differential amplifier circuit 202 to support equalization functions and/or amplifying functions for differential input.

The differential amplifier circuit 202 may also include a second voltage divider 242 between the pre-driver stage 204 and the active transistor(s) 246. The second voltage divider 242 may include one or more resistors connected in parallel with the active transistor(s) 246. The second voltage divider 242 may also be connected to the pre-driver stage 204 via a third output stage resistor 250 and then connected to one of the active transistor(s) 246 with a fourth output stage transistor 254. In some embodiments, the second voltage divider 242 may be configured to set a voltage on the gates of the active transistor(s) 246.

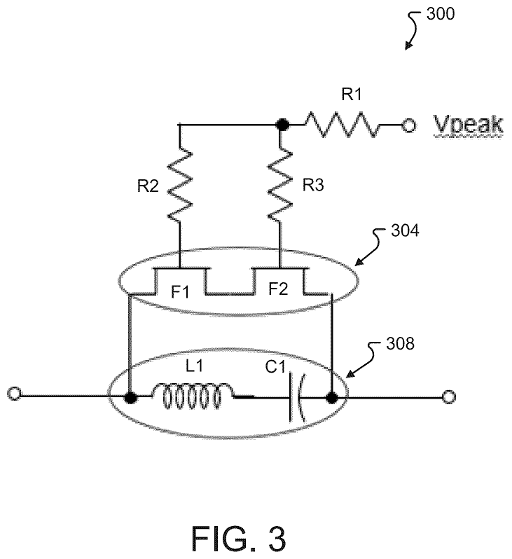

With reference now to FIGS. 3, 4, and 5, various examples of sub-circuits that may be included in the amplifier circuit 200 (or a differential version of amplifier circuit 200) will be described in accordance with at least some embodiments of the present disclosure. FIG. 3 illustrates an example of a first sub-circuit 300 that may be provided as part of an amplifier circuit, such as the amplifier circuit 200.

The first sub-circuit 300 is shown as one example of a sub-circuit that may be incorporated into a single-ended amplifier circuit, such as the amplifier circuit 200. The first sub-circuit 300 is shown to include a pair of variable peaking transistors 304 connected between a resistor network (e.g., resistors R1, R2, and R3) and a resonant LC circuit 308. The resonant LC circuit 308, as the name implies, may include a first inductor L1 and a first capacitor C1 connected in series.

In some embodiments, the pair of variable peaking transistors 304 may act as variable resistors, but parasitic capacitances of the transistors F1, F2 therein may be large enough to act as a capacitance in parallel with the variable resistances of the F1 and F2 transistors. In these cases, the transistors F1 and F2 form a parallel RC network which creates the desired peaking response. In some embodiments, the transistors F1, F2 may be stacked (e.g., two or three) to increase linearity of the amplifier circuit 200. The resonant LC circuit 308 may be configured to reduce losses of the first sub-circuit 300 at high frequencies. In some embodiments, the first sub-circuit 300 may be provided at the input node 236 of the output stage 208 or at some point between the pre-driver stage 204 and the output stage 208.

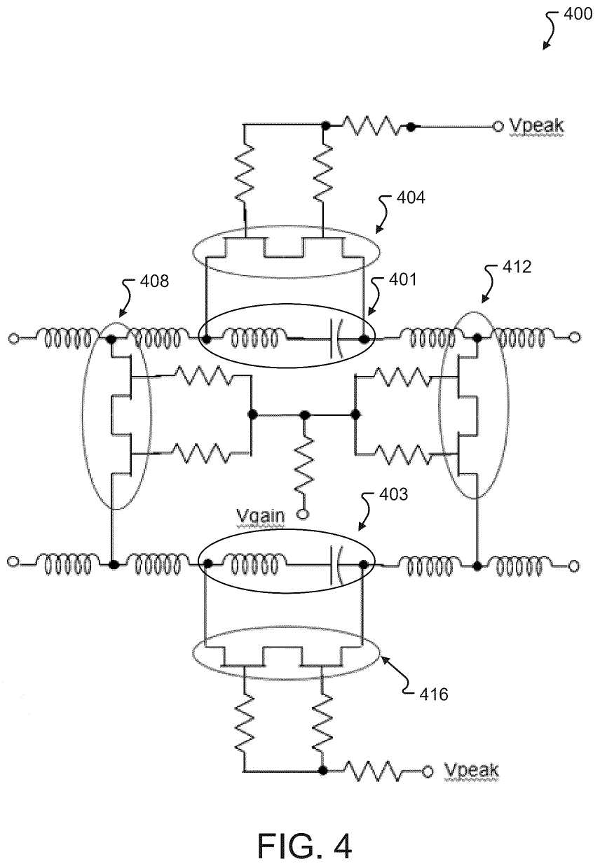

FIG. 4 illustrates an example of a second sub-circuit 400 that may be provided as part of an amplifier circuit, such as a differential version of the amplifier circuit 200. The second sub-circuit 400 may correspond to a variable attenuator/peaking circuit having a first pair of variable peaking transistors 404, a first pair of variable attenuator transistors 408, a second pair of variable attenuator transistors 412, and a second pair of variable peaking transistors 416.

To maintain approximately a 0 dB low frequency gain for some or all preset conditions, it may be desirable to provide a variable attenuator/peaking circuit as part of the amplifier circuit 200. In some embodiments, the transistors of the variable peaking transistors 404, 416 and/or the variable attenuator transistors 408, 412 may be implemented as variable resistors. Additionally, the parasitic capacitance of the variable peaking transistors 404, 416 may be advantageous in forming a peaking response with lower attenuation at high frequencies. The second sub-circuit 400 is also shown to include one or more series inductors to compensate for the capacitance of the transistor(s) of the second sub-circuit 400. The second sub-circuit 400 is also shown to include resonant LC circuits 401 and 403 that reduce losses of the second sub-circuit 400 at high frequencies. Much like the first sub-circuit 300, the second sub-circuit 400 may be provided at the input node 236 of the output stage 208 or at some point between the pre-driver stage 204 and the output stage 208 of a differential amplifier. In both cases, the circuits are DC coupled with very low DC current draw so the output voltage of the pre-driver stage 204 passes through to the input voltage of the output stage 208.

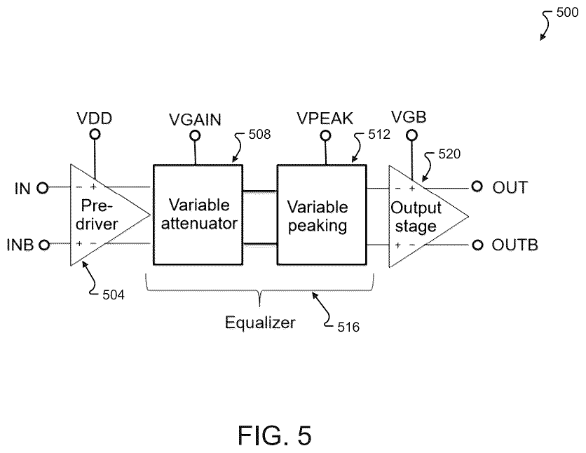

As can be seen in FIG. 5, a block diagram 500 is shown that depicts components that may be included in an amplifier circuit, such as an amplifier circuit 200 or a differential amplifier circuit 202. The block diagram 500 is illustrated to include a pre-driver stage 504, an equalizer circuit 516 comprising a variable attenuator circuit 508 and a variable peaking circuit 512, and an output stage 520. In some embodiments, the variable attenuator circuit 508 may correspond to the attenuator circuits of the second sub-circuit 400 while the variable peaking circuit 512 may correspond to the pair of variable peaking transistors 304 of the first sub-circuit 300 and/or the peaking circuits of the second sub-circuit 400. The variable attenuator circuit 508 and/or the variable peaking circuit 512 may be provided as part of the equalizer circuit 516 connecting the pre-driver stage 504 with the output stage 520. The pre-driver stage 504 may correspond to an example of the pre-driver stage 204 while the output stage 520 may correspond to an example of the output stage 208. In some embodiments, a low gain pre-driver stage 504 may be provided in front of the equalizer circuit 516 to present a good input match and to meet a predetermined gain level since the output stage 520 gain may not be capable of reaching over 15 dB at Nyquist frequency.

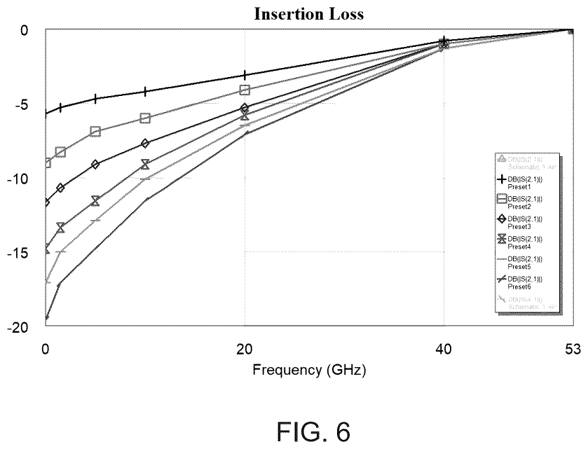

As can be seen in FIG. 6, a plurality of different CTLE profiles may be created between 0 GHz and an upper frequency such as 53 GHZ for various operating parameters of the amplifier circuit 200 and various possible sub-circuit that may be included therein. In some embodiments, different circuit topologies may be used to create different response curves.

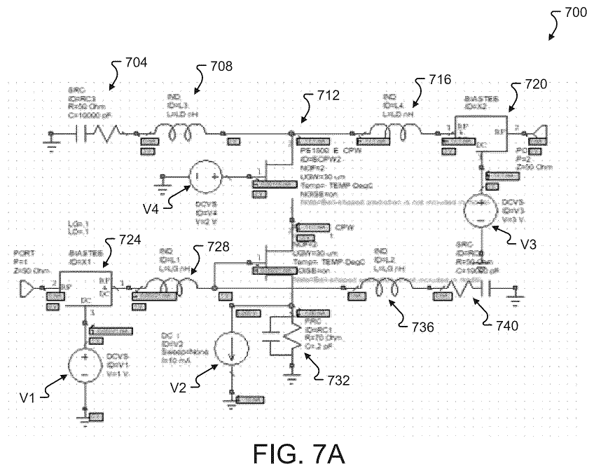

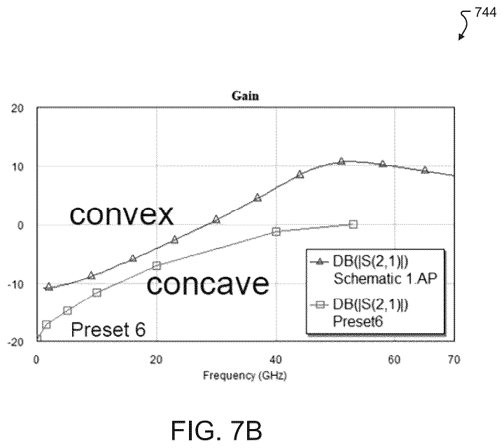

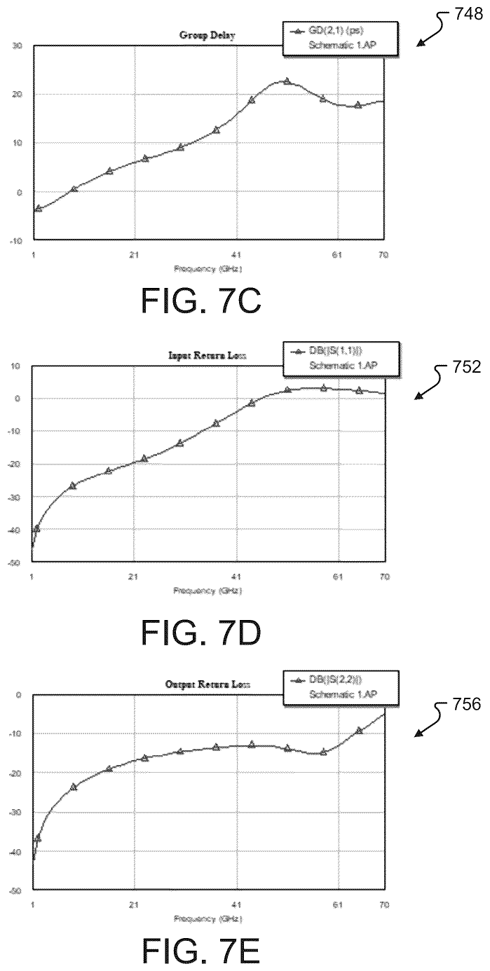

As one example, as shown in FIGS. 7A through 7E, an amplifier circuit 700 may be provided with an active equalizer that includes source degeneration. The amplifier circuit 700 often creates a convex response as shown in the gain response 744 of FIG. 7B. Many communication systems operate better with a concave equalization response rather than a convex equalization response, and embodiments described in this application (e.g., the amplifier circuit 200) may beneficially provide a concave equalization response.

According to the example of FIG. 7A, the amplifier circuit 700 may include a first RC pair 704 (e.g., a series-connected resistor and capacitor) connected in series with a first inductor 708. The output of the first inductor 708 may be connected with a first node 712, that is also connected with an output of a second inductor 716. The second inductor 716 may have an input connected to a first DC bias voltage 720, which is driven by a third input voltage V3.

The first node 712 may be connected to a first end of a pair of transistors. The base of one transistor in the pair of transistors may be further connected to a fourth input voltage V4. The other transistor in the pair of transistors may have its base connected to a third inductor 728, which is further connected to a second DC bias voltage 724, which is driven by a first input voltage V1.

An emitter of the other transistor in the pair of transistors may be connected to a second RC pair 732. The resistor and capacitor in the second RC pair 732 may be connected in parallel with one another.

The base of the other transistor in the pair of transistors may be connected to a third inductor 736, which is connected in series with a third RC pair 740. The resistor and capacitor in the third RC pair 740 may be connected in series with one another.

Inclusion of the amplifier circuit 700 in the amplifier circuit 200 may result in the gain response 744, group delay 748, input return loss 752, and output return loss 756, as shown in FIGS. 7B, 7C, 7D, and 7E, respectively.

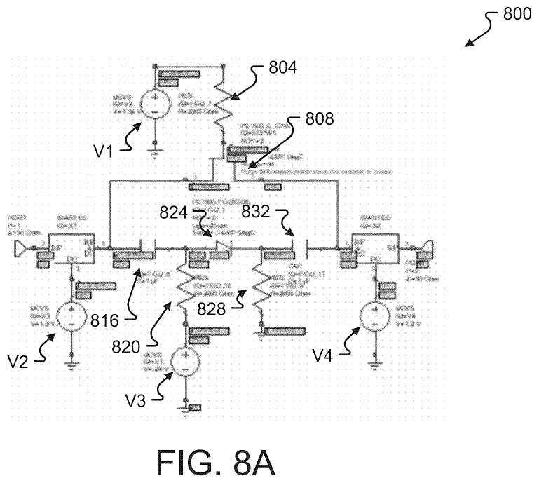

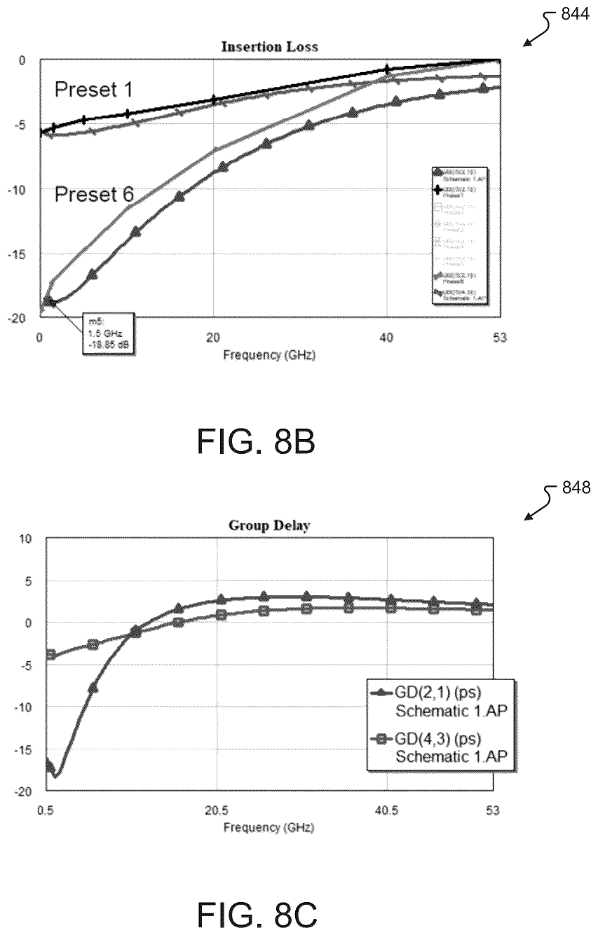

With reference now to FIGS. 8A through 8C, another example of an illustrative equalizer sub-circuit 800 will be described in accordance with at least some embodiments of the present disclosure. The equalizer sub-circuit 800 may correspond to another example of an equalizer circuit 516, which may be incorporated into an amplifier circuit, such as the amplifier circuit 200 (which may be single-ended).

The equalizer sub-circuit 800 is shown to include a number of control voltages V1 and V3, which may be adjusted between a number of different values to achieve different response curves 844, 848 such as those shown in FIGS. 8B and 8C. Voltages V2 and V4 represent the fixed bias voltage that is passed through between the output of the pre-driver stage 204 and the input of the output stage 208 of the amplifier circuit 200. Specifically, but without limitation, an attenuator control voltage at the first voltage V1 may be set between 1.59V (e.g., at a Preset 6 value) and 1.70V (e.g., at a Preset 1 value). The peak control voltage from the voltage V3 may be set between 0.24V (e.g., at the Preset 6 value) and 0.35V (e.g., at the Preset 1 value). Utilizing the above-noted voltages for the attenuator voltage and the peak voltage may help to realize the response curves 844, 848. More specifically, the Preset 1 and Preset 6 values may both realize a substantially negligible insertion loss at relatively high frequencies (e.g., at or above 40 GHz). Similarly, as shown in FIG. 8C, the group delay of the equalizer sub-circuit 800 at either Prest 1 or Preset 6 values may have a substantially similar group delay for operating frequencies at or above 20 GHz.

The equalizer sub-circuit 800 is shown to include a first resistor 804 connected between the first voltage V1 and a first transistor 808. The first voltage V1 adjusts the variable resistance of first transistor 808. In parallel with the first transistor 808 may be connected a pair of capacitors 816, 832 and a diode 824. The capacitors 816, 832 and diode 824 form a variable capacitor in parallel with the variable resistance of first transistor 808 and are DC isolated from the voltages V2 and V4 by capacitors 816 and 832. The third supply voltage V3 in combination with resistors 820, 828 provides a variable current source to control the capacitance of the diode 824. The equalizer sub-circuit 800 provides one example architecture for a single-ended passive equalizer implementation.

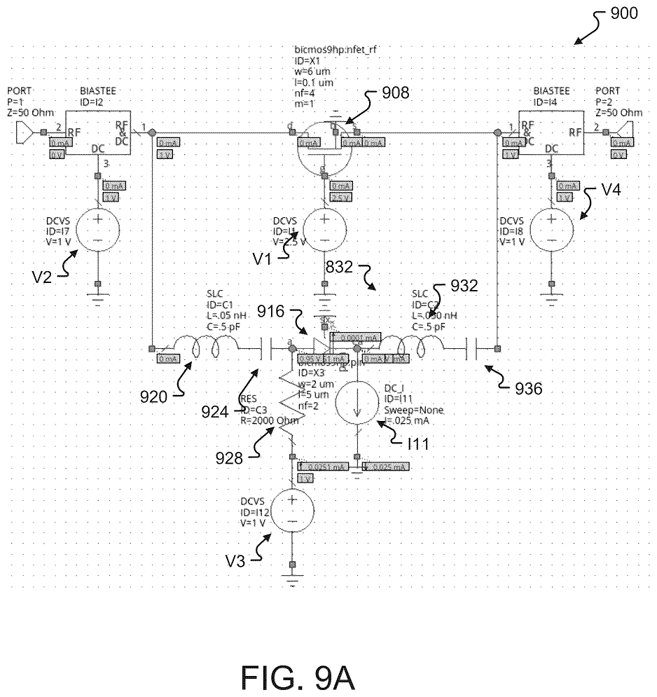

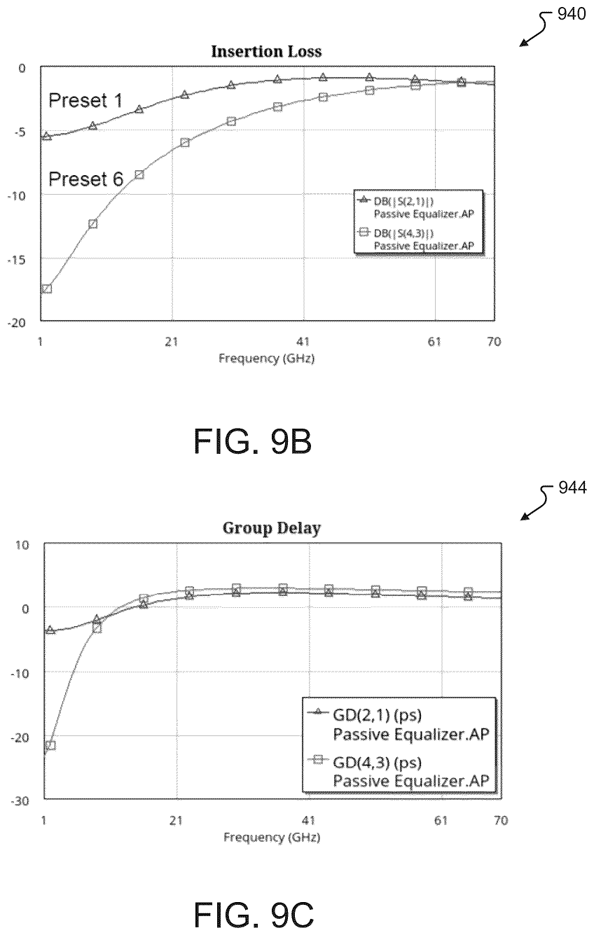

FIG. 9A illustrates another example architecture for a passive equalizer implementation in accordance with at least some embodiments of the present disclosure. Specifically, and without limitation, FIG. 9A illustrates another possible example of an equalizer sub-circuit 900, which may correspond to another example of an equalizer circuit 516, which may be incorporated into a single-ended amplifier circuit, such as the amplifier circuit 200. In one example, the equalizer sub-circuit 900 may be manufactured or formed using a SiGe BiCMOS process.

The equalizer sub-circuit 900 is shown to include a transistor 908 connected between a first bias voltage V2 and a second bias voltage V4. As in the equalizer sub-circuit 800, voltages V2 and V4 represent the fixed bias voltage that is passed through between the output of the pre-driver stage 204, and the input of the output stage 208, of the amplifier circuit 200. The equalizer sub-circuit 900 is also shown to include a control voltage V1, a bias voltage V3, and a control current source I11. The gate of the transistor 908 may be connected to the control voltage V1. The equalizer sub-circuit 900 may further include a first capacitor 924 and first inductor 920 as well as a second capacitor 936 and a second inductor 932. The first capacitor 924 and first inductor 920 may operate as a first DC-blocking capacitor and peaking inductor, respectively, whereas the second capacitor 936 and second inductor 932 may operate as a second DC-blocking capacitor and peaking inductor, respectively.

A diode 916 may be connected between the first DC-blocking capacitor and peaking inductor 924, 920 and the second DC-blocking capacitor and peaking inductor 936, 932. The control current source I11 may provide a peak control current at an output of the diode 916 whereas the bias voltage V3 may be connected at an input of the diode 916 through a resistor 928. The configuration of the equalizer sub-circuit 900, in combination with the amplifier circuit 200, may help to create the insertion loss 940 and group delay 944 illustrated in FIGS. 9B and 9C, respectively.

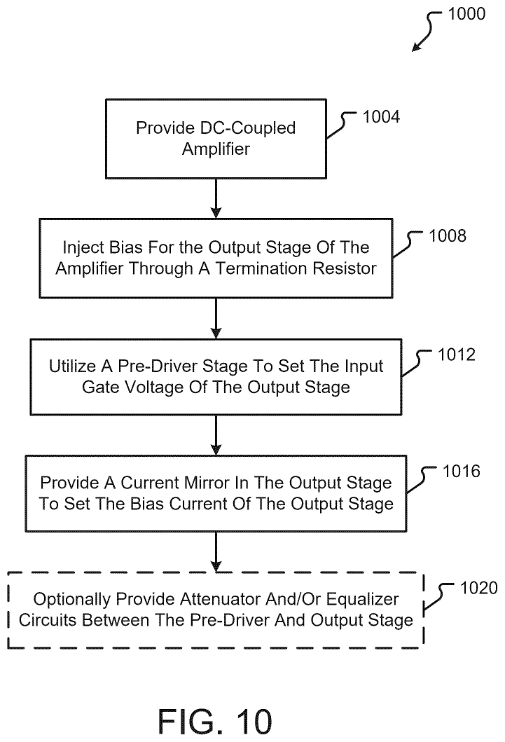

Referring now to FIG. 10, a method 1000 of configuring and operating an amplifier circuit 200, which may be provided as part of a transmission circuit 124 and/or as part of a receiver circuit 128, will be described in accordance with at least some embodiments of the present disclosure. The method 1000 begins by providing a DC-coupled amplifier circuit, such as the amplifier circuit 200 (step 1004). The amplifier circuit 200 may be provided with one or more operating constraints for one or more components thereof. For instance, response curves for the amplifier circuit 200 may be defined or identified as desirable.

The method 1000 may further include injecting a bias for an output stage 208 of the amplifier circuit 200 through a termination resistor (step 1008). The method 1000 may also include a step of utilizing a pre-driver stage 204 to set an input gate voltage for one or more transistors in the output stage 208 (step 1012).

The method 1000 may further include providing a current mirror in the output stage 208 to set a bias current of the output stage (step 1016). The method 1000 may also include an optional step of providing an attenuator and/or equalizer circuit between the pre-driver stage 204 and the output stage 208 (step 1020).

Specific details were given in the description to provide a thorough understanding of the embodiments. However, it will be understood by one of ordinary skill in the art that the embodiments may be practiced without these specific details. In other instances, well-known circuits, processes, algorithms, structures, and techniques may be shown without unnecessary detail in order to avoid obscuring the embodiments.

While illustrative embodiments of the disclosure have been described in detail herein, it is to be understood that the inventive concepts may be otherwise variously embodied and employed, and that the appended claims are intended to be construed to include such variations, except as limited by the prior art.

What is claimed is:

1. A circuit, comprising:
a pre-driver stage comprising a first current mirror that sets a fixed Direct Current (DC) current within the pre-driver stage; and
an output stage coupled with the pre-driver stage and receiving a bias voltage from the pre-driver stage to set an input gate voltage of the output stage, wherein the output stage further comprises a second current mirror to set a bias current of the output stage.

2. The circuit of claim 1, wherein the pre-driver stage further comprises one or more active transistors positioned between the first current mirror and the output stage.

3. The circuit of claim 1, further comprising an equalizer circuit inserted between the pre-driver stage and the output stage, wherein the bias voltage is provided through the equalizer circuit.

4. The circuit of claim 3, wherein the equalizer circuit comprises a variable attenuator portion and a variable peaking portion.

5. The circuit of claim 4, wherein the variable attenuator portion comprises a plurality of series inductors and one or more transistors implemented as variable resistors, wherein the plurality of series inductors compensate for a capacitance of the one or more transistors.

6. The circuit of claim 5, wherein the one or more transistors comprise a plurality of variable gain transistors connected across a plurality of variable peaking transistors.

7. The circuit of claim 1, further comprising:
an active Radio Frequency (RF) transistor provided as part of a cascode, wherein the active RF transistor is provided between the second current mirror and the bias voltage.

8. The circuit of claim 7, wherein the output stage comprises a voltage divider that sets a voltage for a gate of the active RF transistor.

9. The circuit of claim 1, wherein the pre-driver stage and the output stage are formed using a GaAs process.

10. A system, comprising:
a receiver circuit connected between a communication channel and a deserializer, wherein the receiver circuit comprises:
an amplifier having a pre-driver stage and an output stage, wherein the pre-driver stage comprises a first current mirror that sets a fixed Direct Current (DC) current within the pre-driver stage, wherein the output stage is coupled with the pre-driver stage, wherein the output stage receives a bias voltage from the pre-driver stage to set an input gate voltage of the output stage, and wherein the output stage further comprises a second current mirror to set a bias current of the output stage.

11. The system of claim 10, wherein the pre-driver stage further comprises one or more active transistors positioned between the first current mirror and the output stage.

12. The system of claim 10, wherein the amplifier further comprises an equalizer circuit inserted between the pre-driver stage and the output stage, wherein the bias voltage is provided through the equalizer circuit.

13. The system of claim 12, wherein the equalizer circuit comprises a variable attenuator portion and a variable peaking portion.

14. The system of claim 13, wherein the variable attenuator portion comprises a plurality of series inductors and one or more transistors implemented as variable resistors, and wherein the plurality of series inductors compensate for a capacitance of the one or more transistors.

15. The system of claim 14, wherein the one or more transistors comprise a plurality of variable gain transistors connected across a plurality of variable peaking transistors.

16. The system of claim 10, wherein the amplifier further comprises an active Radio Frequency (RF) transistor provided as part of a cascode, wherein the active RF transistor is provided between the second current mirror and the bias voltage.

17. The system of claim 16, wherein the output stage comprises a voltage divider that sets a voltage for a gate of the active RF transistor.

18. The system of claim 10, wherein the pre-driver stage and the output stage are formed using a GaAs process.

19. A method, comprising:
providing a Direct Current (DC)-coupled amplifier with an output stage;
injecting bias for the output stage of the DC-coupled amplifier through a termination resistor;
utilizing a pre-driver stage to set an input gate voltage of the output stage; and
providing a current mirror in the output stage to set a bias current of the output stage.

20. The method of claim 19, further comprising:
providing an equalizer circuit between the pre-driver stage and the output stage, wherein a bias voltage is provided through the equalizer circuit.
